(19) United States
(12) Patent Application Publication
(10) Pub. No.: US 2021/0281213 A1
(43) Pub. Date: Sep. 9, 2021

(54) SYSTEMS AND METHODS OF USING PREDICTED AND OBSERVED SOLAR IRRADIANCE TO OPTIMIZE SOLAR PANEL PERFORMANCE

(71) Applicant: DISH Network L.L.C., Englewood, CO (US)

(72) Inventors: Kevin Kemps Jones, Denver, CO (US); Christopher William Bruhn, Aurora, CO (US)

(21) Appl. No.: 16/809,328

(22) Filed: Mar. 4, 2020

(51) Int. Cl. H02S 40/10; H01L 31/02; H02S 40/40; G01R 19/165; H02S 20/30

(52) U.S. Cl. CPC H02S 40/10; H01L 31/02021; H02S 20/30; G01R 19/16571; H02S 40/40

(57) ABSTRACT

A method includes obtaining a value corresponding to a current amount of power output from a solar panel; determining a value corresponding to an expected amount of power output from the solar panel; comparing the value corresponding to the current amount of power output from the solar panel and the value corresponding to the expected amount of power output from the solar panel of the device; and cleaning the solar panel responsive to determining, based on the comparing, that the value corresponding to the current amount of power output from the solar panel is less than the value corresponding to the expected amount of power output from the solar panel by at least a first threshold value

### TECHNICAL FIELD

The present disclosure relates to devices that are powered by solar energy and more particularly to dynamically modifying the performance of solar panels that provide energy to operate such devices.

### DESCRIPTION OF THE RELATED ART

Conventionally, solar panels that convert solar energy into electrical energy may be used to provide power to electronic devices. The performance of solar panels may deteriorate over time. For example, over time dirt may accumulate on a surface of a solar panel and block sunlight from reaching an array of photovoltaic cells that convert sunlight into electrical energy, which reduces the amount energy output from the solar panel. Accordingly, technicians may be dispatched periodically to clean solar panels. Money can be wasted if a technician is dispatched to clean a solar panel that does not require cleaning. More generally, money can be wasted if a technician is dispatched to service a solar panel that does not require servicing. Accordingly, it is desirable to dispatch a technician to service a solar panel only if the performance of that solar panel is degraded to a level that negatively impacts the performance of a device that receives power from the solar panel.

### BRIEF SUMMARY

The present application teaches devices and methods that dynamically modify the performance of solar panels so that technicians can be dispatched to service the solar panels only if necessary to prevent degradation in the performance of devices that receive power from those solar panels.

A method may be summarized as including obtaining a value corresponding to a current amount of power output from a solar panel, determining a value corresponding to an expected amount of power output from the solar panel, comparing the value corresponding to the current amount of power output from the solar panel and the value corresponding to the expected amount of power output from the solar panel of the device, and cleaning the solar panel responsive to determining, based on the comparing, that the value corresponding to the current amount of power output from the solar panel is less than the value corresponding to the expected amount of power output from the solar panel by at least a first threshold value.

The method also may include transmitting a message indicating that the solar panel is to be serviced responsive to determining, based on the comparing, that the value corresponding to the current amount of power output from the solar panel is less than the value corresponding to the expected amount of power output from the solar panel by at least a second threshold value.

The obtaining the value corresponding to the current amount of power output from the solar panel may include receiving a message that includes data indicating the value corresponding to the current amount of power output from the solar panel. The obtaining the value corresponding to the current amount of power output from the solar panel may include measuring a current flowing out of the solar panel.

The value corresponding to the expected amount of power output from the solar panel may be based on a value of an intensity of light in an area in which the solar panel is located. The value of the intensity of light in the area in which the solar panel may be based on a signal from a light sensor that is coupled to the solar panel.

The cleaning the solar panel may include outputting a signal to a pump that pumps a liquid onto a surface of the solar panel. The cleaning the solar panel may include outputting a signal to a motor that causes a blade to move across a surface of the solar panel. The cleaning the solar panel may include outputting a signal to a motor that causes a gear to rotate and change an orientation of the solar panel. The cleaning the solar panel includes outputting a signal to a heater that causes the heater to heat a surface of the solar panel.

A device may be summarized as including a solar panel, a processor, and a memory coupled to the processor. The memory stores instructions that, when executed by the processor, cause the device to: obtain a value corresponding to a current amount of power output from the solar panel, determine a value corresponding to an expected amount of power output from the solar panel of the device, compare the value corresponding to the current amount of power output from the solar panel and the value corresponding to the expected amount of power output from the solar panel of the device, and cause the solar panel to be cleaned in response to determining that the value corresponding to the current amount of power output from the solar panel is less than the value corresponding to the expected amount of power output from the solar panel by at least a first threshold value.

The memory may store instructions that, when executed by the processor, cause the device to transmit a message indicating that the solar panel is to be serviced responsive to determining that the value corresponding to the current amount of power output from the solar panel is less than the value corresponding to the expected amount of power output from the solar panel by at least a second threshold value.

The memory may store instructions that, when executed by the processor, cause the device to obtain the value corresponding to the current amount of power output from the solar panel based on an amount of current flowing out of the solar panel.

The device may further include a light sensor which, in operation, detects light incident on the light sensor and outputs a signal corresponding to an intensity of the light, and the memory may store instructions that, when executed by the processor, cause the device to obtain the value corresponding to the current amount of power output from the solar panel based on the signal output from the light sensor.

The device may further include a pump which, in operation, pumps a liquid onto a surface of the solar panel, and the memory may store instructions that, when executed by the processor, cause the pump to operate to cause the solar panel to be cleaned.

The device may further include a motor, and a blade coupled to the motor. The motor, in operation, causes the blade to move across a surface of the solar panel, and the memory stores instructions that, when executed by the processor, cause the motor to operate to cause the solar panel to be cleaned.

The device may further include a motor, and a gear coupled to the motor. The motor, in operation, causes the gear to change an orientation of the solar panel, and the memory stores instructions that, when executed by the processor, cause the motor to operate to cause the solar panel to be cleaned.

The device may further include a heater which, in operation, heats a surface of the solar panel, wherein the memory stores instructions that, when executed by the processor, cause the heater to operate to cause the solar panel to be cleaned.

A non-transitory computer-readable medium may be summarized as storing instructions that, when executed by a computer, cause the computer to: obtain a value corresponding to a current amount of power output from a solar panel, determine a value corresponding to an expected amount of power output from the solar panel, compare the value corresponding to the current amount of power output from the solar panel and the value corresponding to the expected amount of power output from the solar panel of the device, and cause the solar panel to be cleaned responsive to determining that the value corresponding to the current amount of power output from the solar panel is less than the value corresponding to the expected amount of power output from the solar panel by at least a first threshold value.

The instructions, when executed by the computer, may cause the computer to transmit a message indicating that the solar panel is to be serviced responsive to determining that the value corresponding to the current amount of power output from the solar panel is less than the value corresponding to the expected amount of power output from the solar panel by at least a second threshold value.

### BRIEF DESCRIPTION OF THE SEVERAL VIEWS OF THE DRAWINGS

FIG. 1 is a block diagram of a system according to one or more embodiments of the present disclosure.

FIG. 2 is a block diagram of a processing device according to one or more embodiments of the present disclosure.

FIG. 3 is a block diagram of a sensor device according to one or more embodiments of the present disclosure.

FIGS. 4A and 4B show an example structure that is capable of changing the orientation of a solar panel according to one or more embodiments of the present disclosure.

FIGS. 5A and 5B show examples of structures capable of cleaning a light-receiving surface of a solar panel according to one or more embodiments of the present disclosure.

FIG. 6 is a flowchart of a method according to one or more embodiments of the present disclosure.

### DETAILED DESCRIPTION

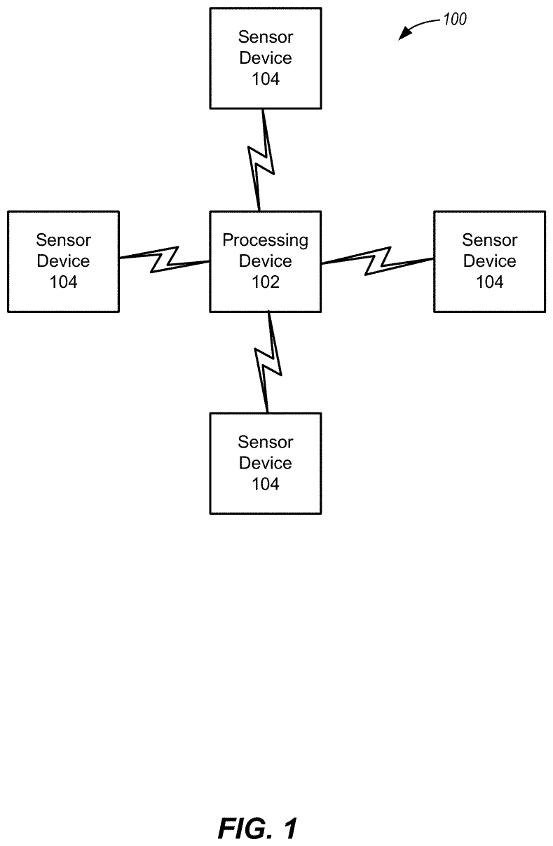

FIG. 1 is a block diagram of a system 100 according to one or more embodiments of the present disclosure. The system 100 includes a processing device 102 and a plurality of sensor devices 104. Although FIG. 1 shows four of the sensor devices 104, the system 100 may include any number of the sensor devices 104. Each of the sensor devices 104 can communicate with the processing device 102. For example, each of the sensor devices 104 can communicate with the processing device 102 via a cellular network.

In one or more embodiments, the sensor devices 104 are air quality monitoring stations including solar panels that provide energy to rechargeable batteries, which provide power to operate those devices. In one or more embodiments, the sensor devices 104 are weather monitoring stations including solar panels that provide energy to batteries that provide power to operate those devices. In one or more embodiments, the sensor devices 104 are located remotely from the processing device 102, and the sensor devices 104 communicate with the processing device 102 using machine-type communications (MTC) or Narrow Band Internet of Things (NB-IoT) technology from the 3rd Generation Partnership Project (3GPP).

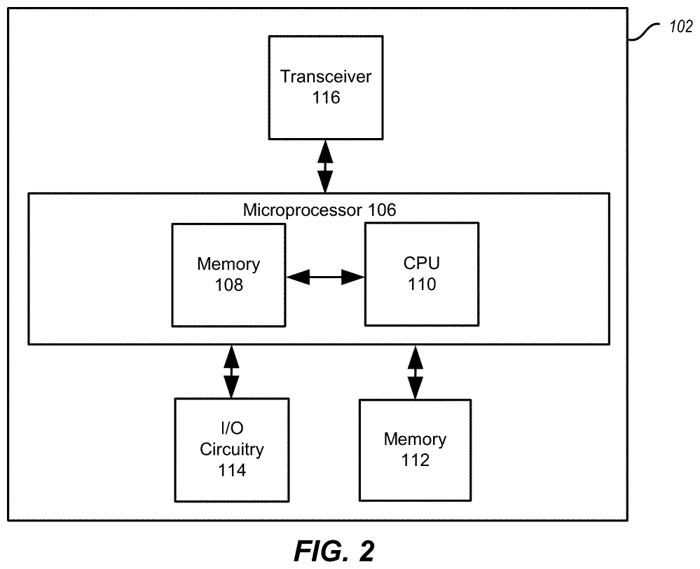

FIG. 2 is a block diagram of a processing device 102 according to one or more embodiments of the present disclosure. The processing device 102 includes a microprocessor 106, which includes a memory 108 and a central processing unit (CPU) 110, a memory 112, input/output (I/O) circuitry 114, and a transceiver 116. In one or more embodiments, the processing device 102 includes a display device (not shown).

In one or more embodiments, the memory 112 stores processor-executable instructions that, when executed by the CPU 110, cause the processing device 102 to perform the functions of the processing device 102 described herein. The CPU 110 uses the memory 108 as a working memory while executing the instructions. In one or more embodiments, the memory 108 is comprised of one or more random access memory (RAM) modules. In one or more embodiments, the memory 112 is comprised of one or more non-volatile random access memory (NVRAM) modules, such as electronically erasable programmable read-only memory (EEPROM) or Flash memory modules, for example.

In one or more embodiments, the I/O circuitry 114 includes buttons, switches, dials, knobs, a touchscreen, or other user-interface elements for inputting commands to the processing device 102. The I/O circuitry 114 also may include a speaker, one or more light emitting devices, or other user-interface elements for outputting information or indications from the processing device 102. The I/O circuitry 114 may include one or more data interfaces, for example, a 40-pin extended general-purpose input/output (GPIO) interface, a universal serial bus (USB) interface, a stereo output and composite video port, a high-definition multimedia interface (HDMI), camera serial interface (CSI), display serial interface (DSI), and a micro secure digital slot (MicroSD slot).

In one or more embodiments, the transceiver 116 is configured to transmit and receive data signals in accordance with the Institute of Electrical and Electronics Engineers (IEEE) 802.3 communication standards. In one or more embodiments, the transceiver 116 is configured to transmit and receive radio frequency (RF) signals in accordance with the Bluetooth (registered trademark) communication standards. In one or more embodiments, the transceiver 116 is configured to transmit and receive RF signals in accordance with the IEEE 802.11 AC communication standards. In one or more embodiments, the transceiver 116 is configured to transmit and receive RF signals in accordance with one or more 3GPP communication standards, including 3G, 4G, 4G Long Term Evolution (LTE), 5G, etc. In one or more embodiments, the transceiver 116 includes a transmitter and a receiver that are provided in a single integrated circuit chip. The transceiver 116 may be configured to transmit and receive signals in accordance with other communications standards without departing from the scope of the present disclosure.

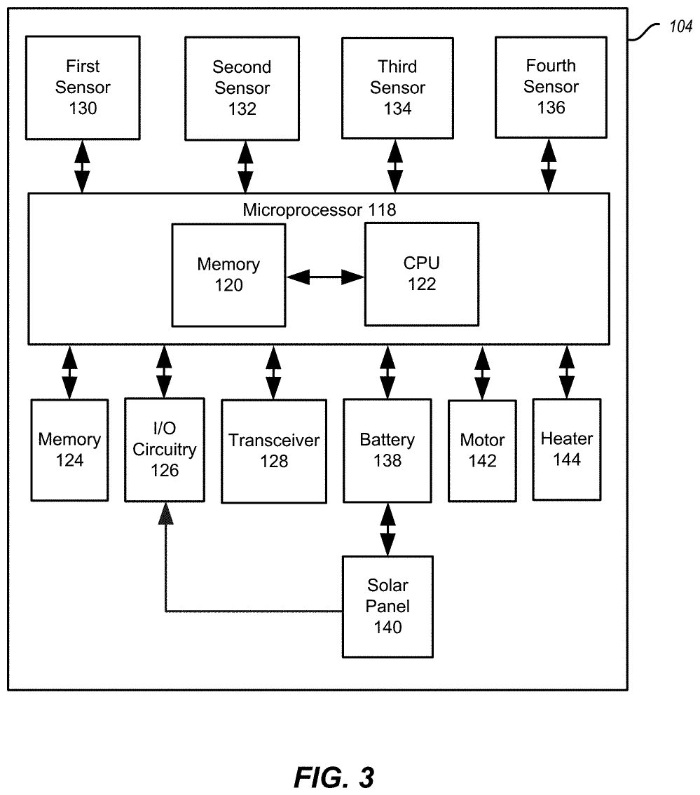

FIG. 3 is a block diagram of a sensor device 104 according to one or more embodiments of the present disclosure. The sensor device 104 includes a microprocessor 118, which includes a memory 120 and a CPU 122, a memory 124, input/output (I/O) circuitry 126, a transceiver 128, a first sensor 130, a second sensor 132, a third sensor 134, a fourth sensor 136, a battery 138, and a solar panel 140. In one or more embodiments, the sensor device 104 includes a motor 142 that is capable of changing an orientation of the solar panel 140. In one or more embodiments, the sensor device 104 includes a heater 144 that is capable of increasing a temperature of the solar panel 140. In one or more embodiments, the sensor device 104 includes a display device (not shown).

In one or more embodiments, the memory 124 stores processor-executable instructions that, when executed by the CPU 122, cause the sensor device 104 to perform the functions of the sensor device 104 described herein. The CPU 122 uses the memory 120 as a working memory while executing the instructions. In one or more embodiments, the memory 120 is comprised of one or more random access memory (RAM) modules. In one or more embodiments, the memory 124 is comprised of one or more non-volatile random access memory (NVRAM) modules, such as electronically erasable programmable read-only memory (EEPROM) or Flash memory modules, for example.

In one or more embodiments, the I/O circuitry 126 includes buttons, switches, dials, knobs, a touchscreen, or other user-interface elements for inputting commands to the sensor device 104. The I/O circuitry 126 also may include a speaker, one or more light emitting devices, or other user-interface elements for outputting information or indications from the sensor device 104. The I/O circuitry 126 may include one or more data interfaces, for example, a 40-pin extended general-purpose input/output (GPIO) interface, a universal serial bus (USB) interface, a stereo output and composite video port, a high-definition multimedia interface (HDMI), camera serial interface (CSI), display serial interface (DSI), and a micro secure digital slot (MicroSD slot). In one or more embodiments, the I/O circuitry 126 includes circuitry that converts a voltage level of a signal output from the solar panel 140 to a voltage level that is suitable for charging the battery 138. In one or more embodiments, the I/O circuitry 126 includes circuitry that converts a voltage level of a control signal output from the microprocessor 118 to a voltage level that is suitable for controlling the motor 142.

In one or more embodiments, the transceiver 128 is configured to transmit and receive RF signals in accordance with one or more 3GPP communication standards, including 3G, 4G, 4G LTE, 5G, etc. In one or more embodiments, the transceiver 128 is configured to transmit and receive data signals in accordance with the IEEE 802.3 communication standards. In one or more embodiments, the transceiver 128 is configured to transmit and receive radio frequency (RF) signals in accordance with the Bluetooth (registered trademark) communication standards. In one or more embodiments, the transceiver 128 is configured to transmit and receive RF signals in accordance with the IEEE 802.11 AC communication standards. In one or more embodiments, the transceiver 116 includes a transmitter and a receiver that are provided in a single integrated circuit chip. The transceiver 128 may be configured to transmit and receive signals in accordance with other communications standards without departing from the scope of the present disclosure.

In one or more embodiments, the first sensor 130 is a temperature sensor that detects a temperature in an area in which the sensor device 104 is located, and outputs a signal or data that indicates the detected temperature.

In one or more embodiments, the second sensor 132 is a wind speed sensor that detects a wind speed in the area in which the sensor device 104 is located, and outputs a signal or data that indicates the detected wind speed.

In one or more embodiments, the third sensor 134 is a pressure sensor that detects a pressure (e.g., atmospheric pressure) in the area in which the sensor device 104 is located, and outputs a signal or data that indicates the detected pressure. In one or more embodiments, the third sensor 134 is a precipitation sensor that detects an amount of precipitation in the area in which the sensor device 104 is located, and outputs a signal or data that indicates the detected amount of precipitation. In one or more embodiments, the third sensor 134 is a humidity sensor that detects an amount of humidity in the area in which the sensor device 104 is located, and outputs a signal or data that indicates the detected amount of humidity.

In one or more embodiments, the fourth sensor 136 is a light sensor that detects a light intensity in one or more visible light band (e.g., visible light band, infrared light band) in the area in which the sensor device 104 is located, and outputs a signal or data that indicates the detected light intensity. In one or more embodiments, the fourth sensor 136 is an image sensor that captures an image and outputs a signal or data corresponding to the captured image.

In one or more embodiments, the fourth sensor 136 is an air quality sensor that detects one or more concentrations of one or more chemicals indicative of air quality in the area in which the sensor device 104 is located, and outputs a signal or data that indicates the detected one or more concentrations of the one or more chemicals.

The first sensor 130, the second sensor 132, the third sensor 134, and the fourth sensor 136 may be different types of sensors than described above without departing from the scope of the present disclosure. Also, the sensor device 104 may include additional or fewer sensors than the first sensor 130, the second sensor 132, the third sensor 134, and the fourth sensor 136 without departing from the scope of the present disclosure

In one or more embodiments, the battery 138 is a lithium-ion battery having an output voltage of 3.7 volts and a capacity of 700 milliamp hours. The battery 138 may be a different type of battery having a different terminal voltage and capacity without departing from the scope of the present disclosure.

In one or more embodiments, the solar panel 140 includes a plurality of photovoltaic solar cells that convert sunlight that illuminates the solar panel 140 into direct current electricity. In one or more embodiments, one or more of the sensor devices 104 includes a plurality of solar panels 140.

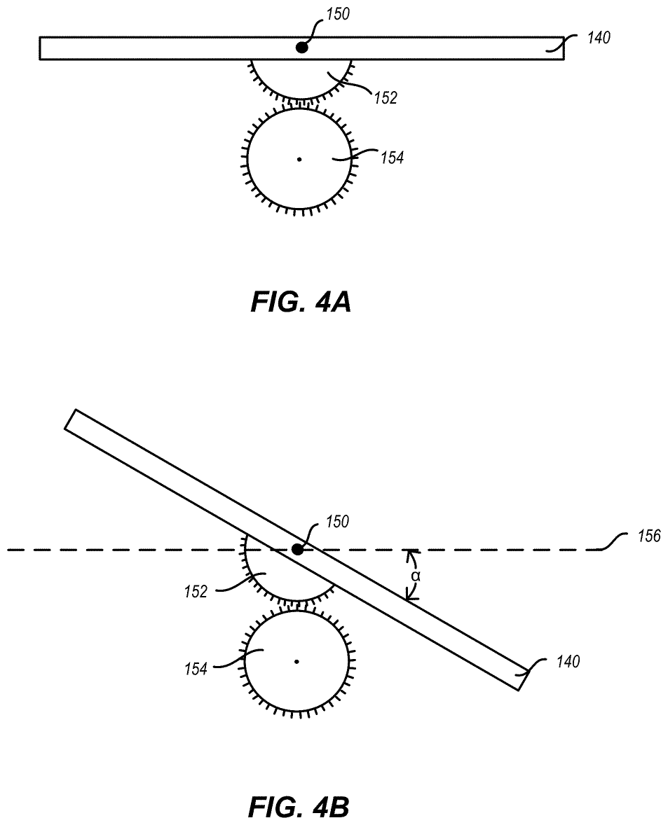

In one or more embodiments, the motor 142 is a stepper motor that is used to change the orientation of the solar panel 140. For example, the solar panel 140 may be mounted to a support structure to which the sensor device 104 is mounted. The rotor of the motor 142 may be coupled to a first gear that is coupled to a second gear that is mounted on the solar panel 140 such that rotation of the rotor causes the first gear to rotate the second gear, which causes the solar panel 140 to pivot in a given direction, as described below with reference to FIGS. 4A and 4B.

In one or more embodiments, the heater 144 includes a heating element formed from one or more wires have a high electrical resistance. The heating element of the heater 144 generates heat when an electrical current flows through the heating element. The heating element of the heater 144 may be arranged on a light-receiving surface of the solar panel 140 in a manner similar to a heating element of a rear defroster is arranged on a rear window of an automobile, for example. The microprocessor 118 of the sensor device 104 may cause an electrical current to flow through the heating element of the heater 144 in order to melt snow or ice that has accumulated on the light-receiving surface of the solar panel 140.

FIGS. 4A and 4B show an example of a structure that is capable of changing the orientation of a solar panel 140 of a sensor device 104 according to one or more embodiments of the present disclosure. More particularly, FIGS. 4A and 4B show a first end of the solar panel 140 having a mounting structure 150 that enables the solar panel 140 to be pivotally mounted to a support structure. Although not shown, a second end of the solar panel, which is opposite to the first end of the solar panel 140 shown in FIG. 4A, includes a similar mounting structure 150.

In one or more embodiments, the mounting structure 150 includes an annular aperture formed in the first and second ends of the solar panel 140. The solar panel 140 is mounted via rods that extend from a support structure, which are inserted into the apertures 150 such that the solar panel 140 is pivotable about the rods.

In one or more embodiments, the mounting structure 150 includes an annular rod 150 that extends from the first and second ends of the solar panel 140. The solar panel 140 is mounted with the rods 150 inserted into apertures formed in a support structure such that the solar panel 140 is pivotable about the rods 150 that extend from the ends of the solar panel 140.

A gear wheel 152 is mounted to a bottom surface of the solar panel 140, for example, using a pair of screws. Rotation of the gear wheel 152 causes the solar panel 140 to pivot via the mounting structure 150 at the first and second ends of the solar panel 140. A gear wheel 154 is mounted to the rotor of the motor 142 such that rotation of rotor causes the gear wheel 154 to rotate. The gear wheel 152 and gear wheel 154 are arranged such that respective teeth of the gear wheel 152 and the gear wheel 154 engage one another.

When the microprocessor 118 of the sensor device 104 controls the motor 142 to rotate in a particular direction by a specified amount in response to a command from the processing device 102, the gear wheel 154 rotates in the particular direction by the specified amount thereby causing the gear wheel 152 to rotate in the opposite direction by the specified amount, which changes the orientation of the solar panel 140. For example, the microprocessor 118 of the sensor device 104 may control the motor 142 to rotate in a counterclockwise direction by a specified amount, which causes the gear wheel 154 to rotate in the counterclockwise direction by the specified amount thereby causing the gear wheel 152 to rotate in the clockwise direction by the specified amount, which causes the solar panel 140 to form an angle α with respect to a predetermined (e.g., horizontal) direction or orientation that is indicated by the dashed line 156 in FIG. 4B.

The processing device 102 may obtain a particular value of the angle α for a solar panel 140 of a particular sensor device 104 that is optimized for a particular period of time (e.g., summer months), for example, based on sets of historical data related to solar intensity or weather and/or predicted weather in an area in which the sensor device 104 is located. The processing device 102 may transmit a message including data indicating the value of the angle α to the sensor device 104, which causes the microprocessor 118 of the sensor device 104 to control the motor 142 to rotate such that the solar panel 140 forms the desired angle α with respect to a reference orientation. In one or more embodiments, the processing device 102 obtains a particular value of the angle α that causes the solar panel 140 to have an orientation in which the solar panel 140 receives a maximum amount of sunlight. In one or more embodiments, the processing device 102 obtains a particular value of the angle α that causes the solar panel 140 to temporarily have an orientation (e.g., α=90 degrees) and gravity causes dirt or melting snow or melting ice to fall off of the solar panel 140, so that the solar panel 140 is able to receive a greater amount of sunlight. The processing device 102 may then obtain another value of the angle α that causes the solar panel 140 to return to its previous orientation (e.g., α=0 degrees).

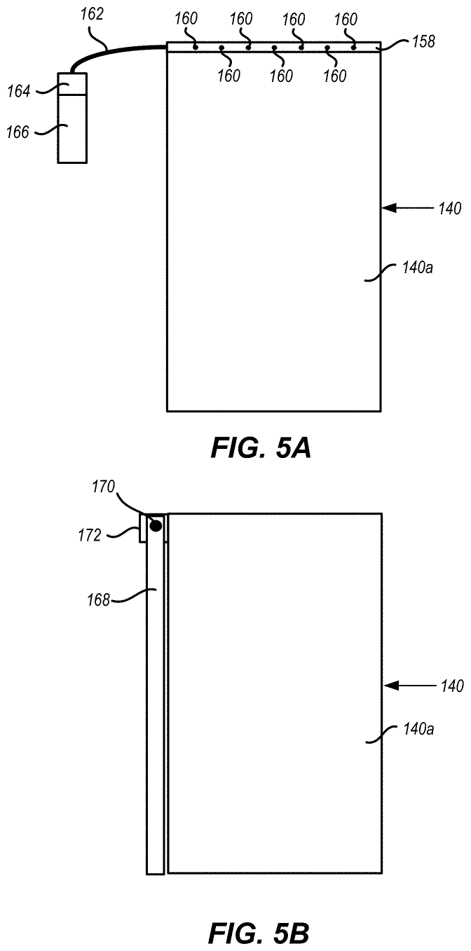

FIGS. 5A and 5B show examples of structures that are capable of cleaning a light-receiving surface 140a of a solar panel 140 of a sensor device 104 according to one or more embodiments of the present disclosure. More particularly, FIG. 5A shows a nozzle 158 that is mounted at one side of a solar panel 140 of a sensor device 104, wherein the nozzle 158 has a plurality of apertures 160 formed therein. The nozzle 158 is fluidly coupled via a tube 162 to a pump 164 that is fluidly coupled to a reservoir 166 containing a cleaning fluid (e.g., a solution of ammonia and water). When the microprocessor 118 of the sensor device 104 outputs a control signal that causes the pump 164 to operate, the pump 164 pumps the cleaning fluid from the reservoir 166 to the nozzle 158 such that the cleaning fluid is output from the apertures 160 onto the light-receiving surface 140a of the solar panel 140. The cleaning fluid may remove dirt that has accumulated on the light-receiving surface 140a of the solar panel 140, thereby cleaning the light-receiving surface 140a of the solar panel 140. After the dirt has been cleaned from the light-receiving surface 140a of the solar panel 140, a greater amount of sunlight can reach the solar panel 140 and, thus, the solar panel 140 can output a greater amount of energy, if the solar panel 140 is functioning properly (e.g., is not damaged).

FIG. 5B shows a squeegee or wiper blade 168 that is mechanically coupled to a shaft 170 that is coupled to a motor 172, which is mounted at one side of a solar panel 140 of a sensor device 104, for example, using a pair of bolts. In one or more embodiments, the wiper blade 168 is similar in many relevant respects to a conventional automobile windshield wiper blade. The shaft 170 is mechanically coupled to the motor 172, for example, in a manner that is similar to the manner in which a conventional automobile windshield wiper blade is mounted for rotation. When the microprocessor 118 of the sensor device 104 controls the motor 172 to operate, the shaft 170 coupled to the motor 142 also rotates thereby causing the wiper blade 168 to move back and forth across the light-receiving surface 140a of the solar panel 140. The wiper blade 168 may remove dirt or snow that has accumulated on the light-receiving surface 140a of the solar panel 140, thereby cleaning the light-receiving surface 140a of the solar panel 140. After the dirt or snow has been cleaned from the light-receiving surface 140a of the solar panel 140, a greater amount of sunlight can reach the solar panel 140 and, thus, the solar panel 140 can output a greater amount of energy, if the solar panel 140 is functioning properly (e.g., is not damaged). In one or more embodiments, at least some of the sensor devices 104 include both of the features described above in connection with FIGS. 5A and 5B.

In one or more embodiments, the processing device 102 is located at a centralized location and the sensor devices 104 are located at geographically dispersed locations. The processing device 102 determines a state of a solar panel 140 of each of the sensor devices 104. If the state of one or more solar panels 140 of the sensor devices 104 indicates that their solar panels 140 should be outputting a greater amount of power, the processing device 102 may then instruct those sensor devices 104 to attempt to clean their solar panels 140. If the processing device 102 determines that the cleaned solar panels 140 should be outputting a greater amount of power, the processing device 102 may then dispatch a technician to service those solar panels 140.

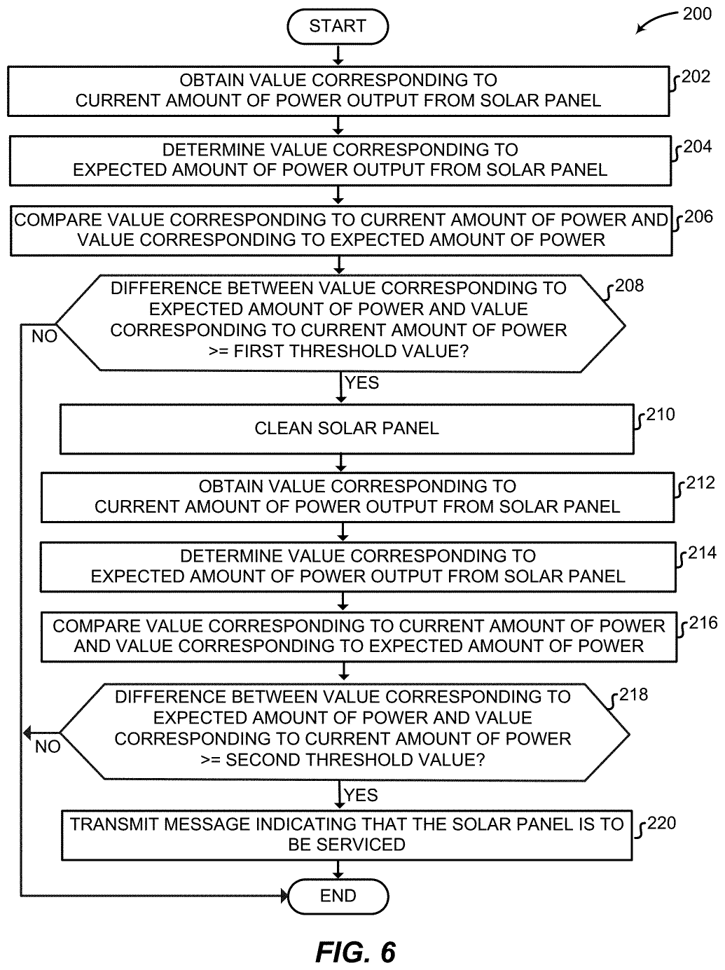

FIG. 6 is a flowchart of a method 200 according to one or more embodiments of the present disclosure. In one or more embodiments, each of the processing devices 104 periodically performs the method 200. In one or more embodiments, the processing device 102 periodically performs the method 200 for each of the sensor devices 104. The method 200 begins at 202.

At 202, a value corresponding to a current amount of power output from a solar panel 140 of a sensor device 104 is obtained. For example, at 202, the microprocessor 118 of the sensor device 104 obtains the value corresponding to the current amount of power output from the solar panel 140 of the sensor device 104 based on signals received from the I/O circuitry 126. More particularly, the microprocessor 118 of the sensor device 104 obtains a first analog signal from a current sensing circuit of the I/O circuitry 126 that measures a current output from the solar panel 140, and converts the first analog signal into a corresponding first digital value using an analog-to-digital converter. The microprocessor 118 of the sensor device 104 also obtains a second analog signal from a voltage sensing circuit of the I/O circuitry 126 that measures a voltage output from the solar panel 140, and converts the second analog signal into a corresponding second digital value using an analog-to-digital converter. The power output of the solar panel 140 is equal to the electrical current output of the solar panel 140 times the voltage output of the solar panel 140. Thus, the microprocessor 118 of the sensor device 104 then obtains the value corresponding to the current amount of power output from the solar panel 140 by multiplying the first digital value by the second digital value. In one or more embodiments, the sensor device 104 transmits to the processing device 102 a message that includes data indicating the value corresponding to the current amount of power output from the solar panel 140, and the microprocessor 106 of the processing device 102 obtains the value from the message at 202. The method 200 then proceeds to 204.

At 204, a value corresponding to an expected amount of power output from the solar panel 140 of the sensor device 104 is determined. For example, at 204, the microprocessor 118 of the sensor device 104 determines the value corresponding to the expected amount of power output from the solar panel 140 of the sensor device 104 from the memory 124, wherein the value is provided by a manufacturer of the solar panel 140.

In one or more embodiments, the microprocessor 118 of the sensor device 104 estimates the value corresponding to the expected amount of power output from the solar panel 140 of the sensor device 104 based on an amount of sunlight currently incident on the solar panel 140. For example, the microprocessor 118 receives from a light sensor (e.g., fourth sensor 136) an analog signal that indicates an intensity of light in the area in which the solar panel 140 is located, and converts the analog signal into a corresponding digital value using an analog-to-digital converter. The microprocessor 118 then uses the resulting value that is based on the output of the light sensor to determine the value corresponding to the expected amount of power output from the solar panel 140. For example, the memory 124 stores a table or other suitable data structure that associates a plurality of light intensity values with a plurality of corresponding power output values of a clean and properly functioning solar panel 140, and the microprocessor 118 uses the resulting value that is based on the output of the light sensor to obtain a power output value from the table that is associated with a light intensity value that most closely matches the resulting value that is based on the output of the light sensor. Additionally, the microprocessor 118 may employ interpolation (e.g., linear interpolation) based on two power output values that are associated with two light intensity values that most closely match the resulting value that is based on the output of the light sensor.

In one or more embodiments, the microprocessor 106 of the processing device 102 estimates the value corresponding to the expected amount of power output from the solar panel 140 of the sensor device 104 based on an amount of sunlight currently incident on the solar panel 140. For example, the processing device 102 receives from the sensor device 104 a message including data indicating an intensity of light in the area in which the solar panel 140 is located, which the sensor device 104 obtains as described above. The microprocessor 106 then uses the received value that is based on the output of the light sensor to determine the expected amount of power output from the solar panel 140. For example, the memory 112 stores a table or other suitable data structure that associates a plurality of light intensity values with a plurality of corresponding power output values of a clean and properly functioning solar panel 140, and the microprocessor 106 uses the received value that is based on the output of the light sensor to obtain a power output value from the table that is associated with a light intensity value that most closely matches the received value that is based on the output of the light sensor. Additionally, the microprocessor 106 may employ interpolation (e.g., linear interpolation) based on two power output values that are associated with two light intensity values that most closely match the received value that is based on the output of the light sensor.

In one or more embodiments, the microprocessor 118 of the sensor device 104 estimates the value corresponding to the expected amount of power output from the solar panel 140 of the sensor device 104 based on an amount of sunlight that is predicted to be incident on the solar panel 140. For example, the memory 124 stores a table or other suitable data structure that associates a plurality of values corresponding to different dates and times with a plurality of corresponding power output values of a clean and properly functioning solar panel 140, and the microprocessor 118 uses a current value of date and time obtained from an internal clock to obtain a power output value from the table that is associated with a value of date and time that most closely matches the current value of date and time obtained from the internal clock. In one or more embodiments, the values in the table stored in the memory 124 are generated based on a set of historical Direct Normal Irradiance (DNI) or Diffuse Horizontal Irradiance (DHI) values (e.g., obtained from the US National Renewable Energy Laboratory (NREL)), that are used to predict corresponding DNI or DHI values for various future dates and times, which are then used to calculate corresponding power output values of a clean and properly functioning solar panel 140, for example, based on experimentation performed using the solar 140 (or a similar solar panel). Additionally, the microprocessor 118 may employ interpolation (e.g., linear interpolation) based on two power output values that are associated with two date and time values that most closely match the date and time value obtained from the internal clock. By way of another example, the microprocessor 118 of the sensor device 104 estimates the value corresponding to the expected amount of power output from the solar panel 140 of the sensor device 104 based on a prediction of the current weather in an area where the solar panel 140 is located.

In one or more embodiments, the microprocessor 106 of the processing device 102 estimates the value corresponding to the expected amount of power output from the solar panel 140 of the sensor device 104 based on an amount of sunlight that is predicted to be incident on the solar panel 140. For example, the memory 112 stores a table or other suitable data structure that associates a plurality of date and time combinations with a plurality of corresponding power output values of a clean and properly functioning solar panel 140, and the microprocessor 106 uses a date and time value are obtained from an internal clock to obtain a power output value from the table that is associated with a stored date and time value that most closely matches the date and time value obtained from the internal clock. In one or more embodiments, the values in the table stored in the memory 112 are generated based on a set of historical DNI or DHI values that are used to predict corresponding DNI or DHI values for various future dates and times, which are then used to calculate corresponding power output values of a clean and properly functioning solar panel 140, for example based on experimentation performed using the solar 140 (or a similar solar panel). Additionally, the microprocessor 106 may employ interpolation (e.g., linear interpolation) based on two power output values that are associated with two date and time values that most closely match the date and time value obtained from the internal clock. The method 200 then proceeds to 206.

At 206, the value corresponding to the current amount of power output from the solar panel 140 that is obtained at 202 and the value corresponding to the expected amount of power output from the solar panel 140 that is determined at 204 are compared. For example, at 206, the value corresponding to the current amount of power output from the solar panel 140 that is obtained at 202 may be divided by the value corresponding to the expected amount of power output from the solar panel 140 that is determined at 204, and the resulting value is stored. By way of another example, at 206, the value corresponding to the current amount of power output from the solar panel 140 that is obtained at 202 may be subtracted from the value corresponding to the expected amount of power output from the solar panel 140 that is determined at 204, and the absolute value of the resulting value is stored. In one or more embodiments, the microprocessor 118 of the sensor device 104 performs the comparison at 206. In one or more embodiments, the microprocessor 106 of the processing device 102 performs the comparison at 206. The method 200 then proceeds to 208.

At 208, a determination is made whether a difference between the value corresponding to the expected amount of power output from the solar panel 140 determined at 204 and the value corresponding to the current amount of power output from the solar panel 140 obtained at 202 is greater than or equal to a first threshold value. For example, at 208, a determination is made whether the difference between the value corresponding to the expected amount of power output from the solar panel 140 determined at 204 and the value corresponding to the current amount of power output from the solar panel 140 obtained at 202 is greater than or equal to a predetermined value. For example, if the measured power needs to be within 2 W of the expected power (i.e., 2 W is a threshold value), the expected power is 10 W, and the measured power is 7 W, then the difference between expected power and measured power is 3 W; because 3 W is greater than the threshold of 2 W, the situation needs to be remedied. In one or more embodiments, the microprocessor 118 of the sensor device 104 makes the determination at 208. In one or more embodiments, the microprocessor 106 of the processing device 102 makes the determination at 208.

If the difference between the value corresponding to the expected amount of power output from the solar panel 140 determined at 204 and the value corresponding to the current amount of power output from the solar panel 140 obtained at 202 is not determined to be greater than or equal to the first threshold value, the method 200 then ends (or is repeated). If the difference between the value corresponding to the expected amount of power output from the solar panel 140 obtained at 204 and the value corresponding to the current amount of power output from the solar panel 140 obtained at 202 is determined to be greater than or equal to the first threshold value, the method 200 then proceeds to 210.

At 210, the solar panel 140 is cleaned. For example, at 210, the microprocessor 118 of the sensor device 104 outputs a control signal to the pump 164 that causes the pump 164 to move the cleaning fluid from the reservoir 166 to the nozzle 158 such that the cleaning fluid is output from the apertures 160 onto the surface 140a of the solar panel 140, as described above in connection with FIG. 5A. Additionally or alternatively, the microprocessor 118 of the sensor device 104 may output a control signal to the motor 172 that causes the wiper blade 168 to move across the surface 140a of the solar panel 140 to remove the cleaning fluid and dirt from the solar panel 140, as described above in connection with FIG. 5B. Additionally or alternatively, the microprocessor 118 of the sensor device 104 may output a control signal to the heater 144 that causes the heater 144 to generate heat. Additionally or alternatively, the microprocessor 118 of the sensor device 104 may output a control signal to the motor 142 that causes the orientation of the solar panel 140 to change (e.g., a equals 90 degrees) such that gravity causes the dirt (and possibly cleaning fluid) to fall off of the solar panel, described above in connection with FIGS. 4A and 4B. In one or more embodiments, at 210, the sensor device 104 performs the above-described acts in response to receiving a message from the processing device 102. The method 200 then proceeds to 212.

At 212, a value corresponding to a current amount of power output from the solar panel 140 of the sensor device 104 is obtained. In one or more embodiments, the value corresponding to the current amount of power output from the solar panel 140 of the sensor device 104 is obtained at 212 in the same manner as obtained at 202, as described above. The method 200 then proceeds to 214.

At 214, a value corresponding to an expected amount of power output from the solar panel 140 of the sensor device 104 is determined. In one or more embodiments, the value corresponding to the expected amount of power output from the solar panel 140 of the sensor device 104 is determined at 214 in the same manner as obtained at 204, as described above. In one or more embodiments, the method 200 does not include 214 and, instead, the value obtained at 204 is used at 216. The method 200 then proceeds to 216.

At 216, the value corresponding to the current amount of power output from the solar panel 140 that is obtained at 212 and the value corresponding to the expected amount of power output from the solar panel 140 that is determined at 214 (or 204) are compared. In one or more embodiments, the value corresponding to the current amount of power output from the solar panel 140 that is obtained at 212 and the value corresponding to the expected amount of power output from the solar panel 140 that is determined at 214 (or 204) are compared in the same manner as obtained at 206, as described above. The method 200 then proceeds to 218.

At 218, a determination is made whether a difference between the value corresponding to the current amount of power output from the solar panel 140 obtained at 212 and the value corresponding to the expected amount of power output from the solar panel 140 determined at 214 (or 204) is greater than or equal to a second threshold value. For example, the second threshold value corresponds to 70 percent of the expected amount of power output from the solar panel 140 determined at 214 (or 204). In one or more embodiments, the determination is made at 218 in the same manner as the determination made at 208, as described above. In one or more embodiments, the second value is greater than the first threshold value. For example, the first threshold value may correspond to a fifteen percent reduction in power output, and the second threshold value may correspond to a thirty percent reduction in power output. The method 200 then proceeds to 220.

At 220, a message indicating that the solar panel 140 is to be serviced is transmitted. For example, the message includes one or more of a unique identifier of the sensor device 104, a location of the sensor device 104, a time at which the message is generated, a value indicating the current amount of power output from the solar panel 140 at that time, a value indicating the expected amount of power output from the solar panel 140 at that time, or a ratio thereof. The message may be transmitted to a particular service center or technician located in the vicinity of the solar panel 140. In one or more embodiments, the sensor device 104 transmits the message at 220. In one or more embodiments, the processing device 102 transmits the message at 220. In one or more embodiments the method 200 then ends. In one or more embodiments the method 200 then returns to 202 and the method 200 is repeated.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method comprising:
obtaining a value corresponding to a current amount of power output from a solar panel;
determining a value corresponding to an expected amount of power output from the solar panel;
comparing the value corresponding to the current amount of power output from the solar panel and the value corresponding to the expected amount of power output from the solar panel of the device; and
cleaning the solar panel responsive to determining, based on the comparing, that the value corresponding to the current amount of power output from the solar panel is less than the value corresponding to the expected amount of power output from the solar panel by at least a first threshold value.

2. The method according to claim 1, further comprising:
transmitting a message indicating that the solar panel is to be serviced responsive to determining, based on the comparing, that the value corresponding to the current amount of power output from the solar panel is less than the value corresponding to the expected amount of power output from the solar panel by at least a second threshold value.

3. The method according to claim 1, wherein the obtaining the value corresponding to the current amount of power output from the solar panel includes receiving a message that includes data indicating the value corresponding to the current amount of power output from the solar panel.

4. The method according to claim 1, wherein the obtaining the value corresponding to the current amount of power output from the solar panel includes measuring a current flowing out of the solar panel.

5. The method according to claim 1, wherein the value corresponding to the expected amount of power output from the solar panel is based on a value of an intensity of light in an area in which the solar panel is located.

6. The method according to claim 5, wherein the value of the intensity of light in the area in which the solar panel is based on a signal from a light sensor that is coupled to the solar panel.

7. The method according to claim 1, wherein the cleaning the solar panel includes outputting a signal to a pump that pumps a liquid onto a surface of the solar panel.

8. The method according to claim 1, wherein the cleaning the solar panel includes outputting a signal to a motor that causes a blade to move across a surface of the solar panel.

9. The method according to claim 1, wherein the cleaning the solar panel includes outputting a signal to a motor that causes a gear to rotate and change an orientation of the solar panel.

10. The method according to claim 1, wherein the cleaning the solar panel includes outputting a signal to a heater that causes the heater to heat a surface of the solar panel.

11. A device comprising:
a solar panel;
a processor; and
a memory coupled to the processor, the memory storing instructions that, when executed by the processor, cause the device to:
obtain a value corresponding to a current amount of power output from the solar panel;
determine a value corresponding to an expected amount of power output from the solar panel of the device;
compare the value corresponding to the current amount of power output from the solar panel and the value corresponding to the expected amount of power output from the solar panel of the device; and
cause the solar panel to be cleaned in response to determining that the value corresponding to the current amount of power output from the solar panel is less than the value corresponding to the expected amount of power output from the solar panel by at least a first threshold value.

12. The device according to claim 11, wherein the memory stores instructions that, when executed by the processor, cause the device to:
transmit a message indicating that the solar panel is to be serviced responsive to determining that the value corresponding to the current amount of power output from the solar panel is less than the value corresponding to the expected amount of power output from the solar panel by at least a second threshold value.

13. The device according to claim 11, wherein the memory stores instructions that, when executed by the processor, cause the device to obtain the value corresponding to the current amount of power output from the solar panel based on an amount of current flowing out of the solar panel.

14. The device according to claim 11, further comprising:
a light sensor which, in operation, detects light incident on the light sensor and outputs a signal corresponding to an intensity of the light, wherein the memory stores instructions that, when executed by the processor, cause the device to obtain the value corresponding to the current amount of power output from the solar panel based on the signal output from the light sensor.

15. The device according to claim 11, further comprising:
a pump which, in operation, pumps a liquid onto a surface of the solar panel, wherein the memory stores instructions that, when executed by the processor, cause the pump to operate to cause the solar panel to be cleaned.

16. The device according to claim 11, further comprising:
a motor; and
a blade coupled to the motor,
wherein the motor, in operation, causes the blade to move across a surface of the solar panel, and the memory stores instructions that, when executed by the processor, cause the motor to operate to cause the solar panel to be cleaned.

17. The device according to claim 11, further comprising:
a motor; and
a gear coupled to the motor,
wherein the motor, in operation, causes the gear to change an orientation of the solar panel, and the memory stores instructions that, when executed by the processor, cause the motor to operate to cause the solar panel to be cleaned.

18. The device according to claim 11, further comprising:
a heater which, in operation, heats a surface of the solar panel, wherein the memory stores instructions that, when executed by the processor, cause the heater to operate to cause the solar panel to be cleaned.

19. A non-transitory computer-readable medium storing instructions that, when executed by a computer, cause the computer to:
obtain a value corresponding to a current amount of power output from a solar panel;
determine a value corresponding to an expected amount of power output from the solar panel;
compare the value corresponding to the current amount of power output from the solar panel and the value corresponding to the expected amount of power output from the solar panel of the device; and
cause the solar panel to be cleaned responsive to determining that the value corresponding to the current amount of power output from the solar panel is less than the value corresponding to the expected amount of power output from the solar panel by at least a first threshold value.

20. The computer-readable medium according to claim 19, wherein the instructions, when executed by the computer, cause the computer to:
transmit a message indicating that the solar panel is to be serviced responsive to determining that the value corresponding to the current amount of power output from the solar panel is less than the value corresponding to the expected amount of power output from the solar panel by at least a second threshold value.
